(19) United States
(12) Patent Application Publication
(10) Pub. No.: US 2002/0061659 A1
(43) Pub. Date: May 23, 2002

(54) Method for manufacturing a semiconductor device

(75) Inventor: Takayuki Abe, Tokyo (JP)

Correspondence Address: SUGHRUE, MION, ZINN, MACPEAK & SEAS, PLLC, 2100 Pennsylvania Avenue, N.W., Washington, DC, 20037-3213, US

(73) Assignee: NEC CORPORATION

(21) Appl. No.: 09/987,247

(22) Filed: Nov. 14, 2001

(30) Foreign Application Priority Data
Nov. 20, 2000 (JP) 352483/2000

(51) Int. Cl. H01L 21/31

(52) U.S. Cl. 438/791

(57) ABSTRACT

A method for manufacturing a semiconductor device by thermal CVD with NH₃ and SiHₓF₄₋ₓ (x=0, 1, 2, 3 or 4) used as reactive gases comprising the step of setting the pressure of reactive gases in a reaction chamber in the range of 1×10⁴ to 6×10⁴ Pa, thereby forming a silicon nitride film on the surface of a pattern where each lead has an enhanced step, printed on a semiconductor substrate.

### BACKGROUND OF THE INVENTION

1. Field of the Invention

The present invention relates to a method for manufacturing a semiconductor device, particularly to a method for forming a silicon nitride film.

2. Description of the Prior Art

Compaction and high-density integration of semiconductor elements are being vigorously promoted as before, and currently semiconductor devices based on ultra highly integrated circuits such as logic devices which are designed according to a size standard of about 0.15 μm, or memory devices incorporating a 1 Giga-bit dynamic random access memory (GbDRAM) are developed and their pilot products prepared. Indeed, a miniature version of the above memory device based on the same design standards such as a 256 Mb DRAM is being put to the market. However, with the highly dense compaction of a semiconductor device as mentioned above, it becomes extremely difficult to prepare a contact hole which is essential for the structure of a semiconductor element.

Conventionally, the fabrication of a semiconductor device consists of sequentially placing patterns formed on the layers made of different materials such as a metal film, a semiconductor film, an insulator film or the like one over another, to produce a semiconductor element with a fine structure. If it is required to place one pattern over another in the photolithography process in the fabrication of a semiconductor element, a mask must be properly aligned with the underlying pattern formed in the previous step (alignment), and then the overlying pattern must be formed thereupon. The same applies to the formation of a fine contact hole.

However, the marginal area which is inevitably introduced as a result of the mask alignment based on the conventional method as above emerges as a grave disturbing factor when circuit components must be disposed at a high density for the formation of a semiconductor element. The disturbance due to the marginal area inevitably introduced as a result of the conventional mask alignment becomes more manifest with the increased compaction of a semiconductor element. To cope with this disadvantage, various methods have been proposed whereby contact holes are prepared through self-alignment contact (SAC hereinafter) in the underlying pattern. For example, a representative SAC technique is described in Japanese Patent Laid-Open No. 10-189721.

It is customary according to the conventional SAC technique to coat a silicon nitride film on the underlying pattern as is indicated in the disclosure given by the above laid-open publication. To prepare a properly formed silicon nitride film, deposition of a silicon nitride film excellent in step coverage is essential.

The deposition of a silicon nitride film may occur by various methods, but there is chemical vapor deposition (CVD) which is excellent in that it allows the formation of a silicon nitride film excellent in step coverage. Among the methods based on chemical vapor deposition, the one based on thermal CVD is generally better than the one based on plasma excitation CVD (PECVD). However, even with the method based on thermal CVD, the step coverage becomes degraded with the increased compaction encountered with a recent semiconductor element. This is because the aspect ratio of each lead constituting the underlying pattern increases with the increased compaction of the pattern.

Formation of a silicon nitride film according to a conventional technique (conventional thermal CVD hereinafter) will be described with reference to FIG. 9. FIG. 9 shows a cross-section of a wiring portion where a silicon nitride film has been formed so as to cover leads constituting an underlying wiring pattern each of which has an emphasized top-base step as a result of the increased aspect ratio. According to this conventional technique, a silicon nitride film is deposited at 700 to 800° C. by the reduced pressure CVD. In this method, silane (SiH4) and ammonia (NH3) are used as reactive gases. Then, nitrogen (N2) is introduced as a carrier gas such that the pressure of total gases can be kept at about 10 to 100 Pa. Keeping the pressure of gases at such a low level as indicated above during the processing based on CVD is essential, because the film forming apparatus is a reaction furnace suitable for batch treatment, and because the thickness of a film between adjacent wafers must be kept uniform.

As shown in FIG. 9, there are provided leads 102, 102a parallel with each other on the surface of an inter-layer insulating film 101 over a silicon substrate (not illustrated here). Let's assume the design standard of the semiconductor device is set to 0.15 μm. Then, the width of each lead 102, 102a, and the interval between the two leads are determined to be 0.2 μm. In other words, leads with a pitch of 0.4 μm are formed. In this particular example, leads 102, 102a are made of a high-melting point metal such as tungsten (W), or its nitride such as tungsten nitride (WN), and has a thickness of 100 nm. Further, upon leads 102, 102a, are formed masks 103, 103a composed of a nitride film. In this particular example, masks 103, 103a of a nitride film has a thickness of about 300 nm.

In this manner, are formed lead 102, and mask 103 of a nitride film, and lead 102a, and mask 103a of a nitride film which constitute the underlying pattern. Thus, the aspect ratio of each component constituting the underlying pattern becomes about 2. In this manner, the wiring pattern where each component has a large top-base step is formed over the inter-layer insulating film 101.

Over the basement structure as configured above, a silicon nitride film having a thickness of about 50 nm is deposited by the conventional thermal CVD as described above. In this manner, a blanket nitride film 104 is formed over the inter-layer insulating film 101 so as to intimately cover the top and lateral surfaces of each component of the wiring pattern thereupon. In this operation, according to the conventional thermal CVD, deposition of the blanket nitride film 104 occurs non-uniformly: it is comparatively thick on the top surface of the component while it is comparatively thin on the lateral surface of the same as shown in FIG. 9. Namely, the blanket nitride film 104 forms an overhang at the corner of the top-base step which has a large aspect ratio.

The increased height of the top-base step as described above becomes more manifest with the increased compaction of semiconductor devices such as memory devices or logic devices. Moreover, the aspect ratio of a trench capacitor, i.e., the ratio of the depth against the width of trench also increases in the same manner with that of each lead constituting a wiring pattern. Namely, if a silicon nitride film is formed in such a trench as described above, the silicon nitride film will show an overhang in the manner as mentioned above.

As discussed above, with the increased compaction of a semiconductor device, the aspect ratio of each component of a wiring pattern necessary for the formation of a semiconductor device will inevitably become large. Thus, if a silicon nitride film is formed over the surface of a pattern where each component has a large top-base step, its step coverage will be impaired.

A further description will be given about the reason for this with reference to FIG. 9. In order to form a silicon nitride film by a conventional thermal CVD, SiH4 and NH3 are introduced into a reaction furnace as reactive gases which will undergo thermal decomposition being exposed to a film-forming temperature to dissociate themselves into active molecules 105, 105a and 105b such as SiH2, NH and the like, as shown in FIG. 9, which are then adsorbed as a result of thermal agitation to a region where art a film will be formed. Then, those molecules will undergo surface migrations to react with each other. However, the migration in this case is very minute.

Let's assume here the pressure of all the gases in the furnace is about 100 Pa. Then, the average free travel distance of active molecules 105, 105a and 105b will be about several μm. The magnitude of this average free travel distance is represented by the length of the arrow in FIG. 9 for each active molecule. As is obvious from FIG. 9, if the interval between adjacent components of a pattern is made too small with respect to the above-described average free travel distance, an active molecule thermally agitated in one direction will not be able to reach the space between adjacent components, that is, the inter-component space. In FIG. 9, active molecule 105 can enter an inter-component space, whereas active molecules 105a and 105b will be intercepted by leads and will not be able to reach a space in question. Namely, the shadowing effect is manifest here. Because of this, as discussed above, provided that each lead of a pattern has a large aspect ratio, a comparatively thick silicon nitride film is deposited on the top surface of a lead while a comparatively thin silicon nitride film is deposited on its lateral surfaces and a base between adjacent leads. Thus, such an overhang as described above develops at the corner of a top-base step of a lead.

The principal object of this invention is to provide a method for forming a silicon nitride film with a high step coverage even when the film is applied on a pattern of a highly compacted semiconductor device where each lead shows an emphasized top-base step. A further object of this invention is to provide a method whereby it is possible to easily control the formation of such a silicon nitride film as above, and to easily adapt the formation of a silicon nitride film to be suitable for the mass-production of semiconductor devices.

### BRIEF SUMMARY OF THE INVENTION

Objects of the Invention

The object of this invention is to provide a method for forming a silicon nitride film with a high step coverage even when the film is applied on a pattern of a highly compacted semiconductor device where each lead shows an emphasized top-base step.

### SUMMARY OF THE INVENTION

The method for fabricating a semiconductor device by thermal CVD using NH₃ and SiHₓF₄₋ₓ (x=0, 1, 2, 3 or 4) as reactive gases comprises the steps of setting the pressure of reactive gases in the reaction chamber in a range from 1×10⁴ to 6×10⁴ Pa, and of forming a silicon nitride film on the surface of a pattern over a semiconductor substrate where each lead component has an emphasized top-base step.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIG. 1 is a sketchy cross-section of a reaction chamber used for thermal CVD which is introduced for the illustration of a first example of this invention;

FIG. 2 is a cross-section of a wiring portion which has a silicon nitride film coated thereupon, the silicon nitride film being applied to cover the entire wiring pattern;

FIG. 3 is a graph for illustrating the control condition required when a silicon nitride film is formed according to the method of this invention;

FIG. 4 is a graph for explaining the reason why a silicon nitride film prepared according to this method enjoys a high step coverage;

FIG. 5 is a graph for illustrating the insulating activity of a silicon nitride film prepared according to this invention;

FIGS. 6A, 6B are the cross-sections of a second example of this invention for illustrating the sequential steps required for the formation of contact holes thereupon;

FIGS. 7A, 7B are the cross-sections of the same example for illustrating the sequential steps subsequent to the steps of FIG. 6;

FIG. 8 is a cross-section of a capacitor for illustrating a third example of this invention; and

FIG. 9 is a cross-section of a wiring portion introduced for the illustration of a conventional technique which has a silicon nitride film coated thereupon, the silicon nitride film being applied to cover the entire wiring pattern.

### DETAILED DESCRIPTION OF THE INVENTION

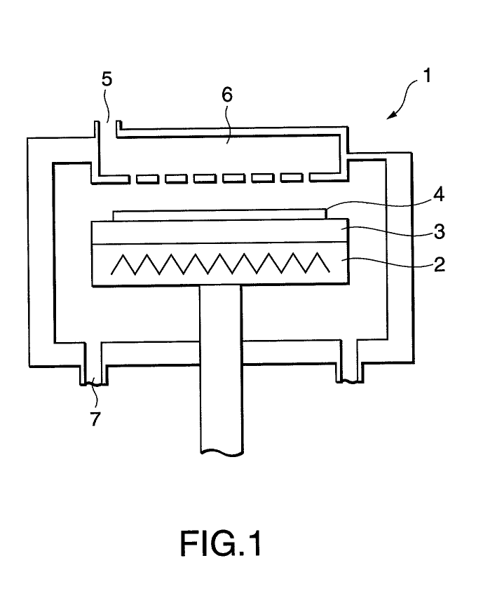

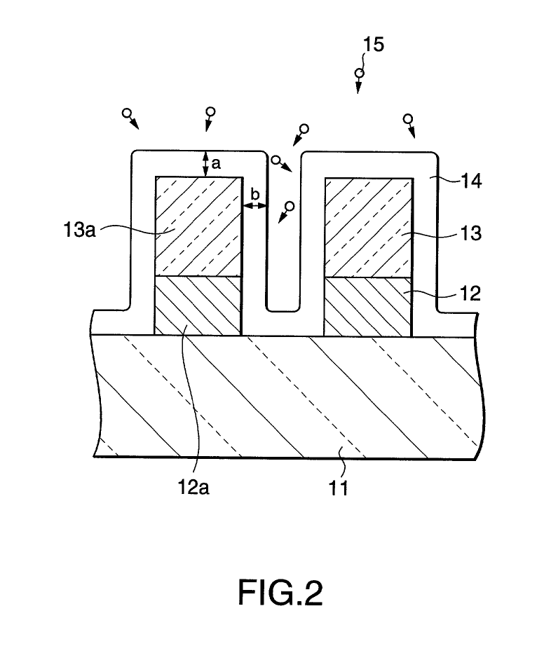

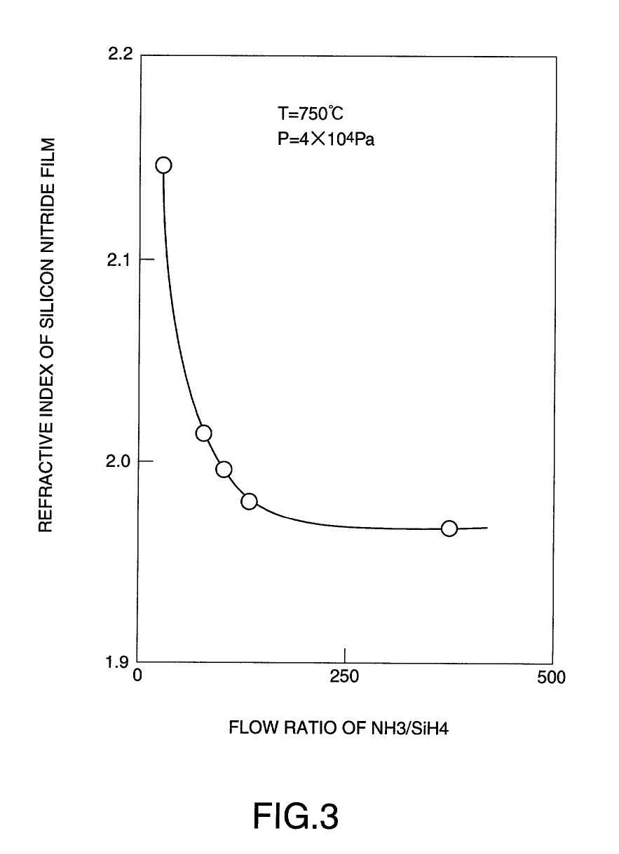

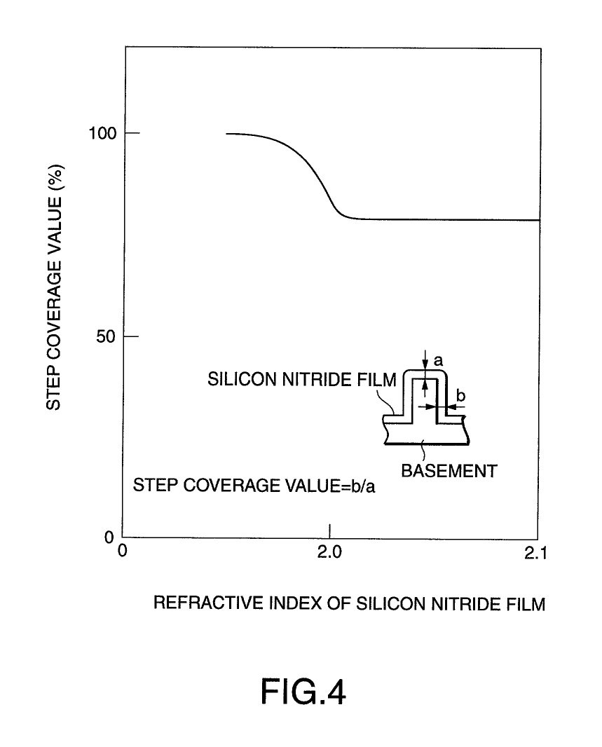

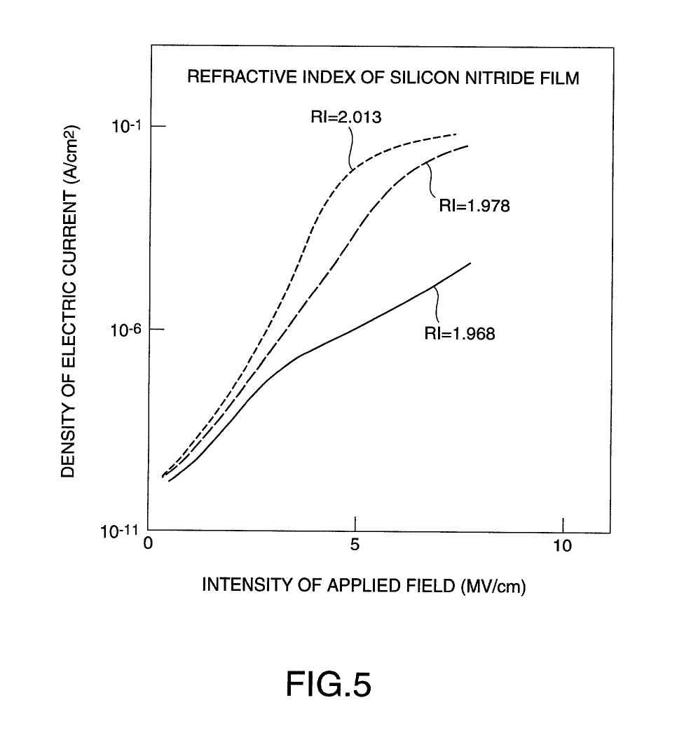

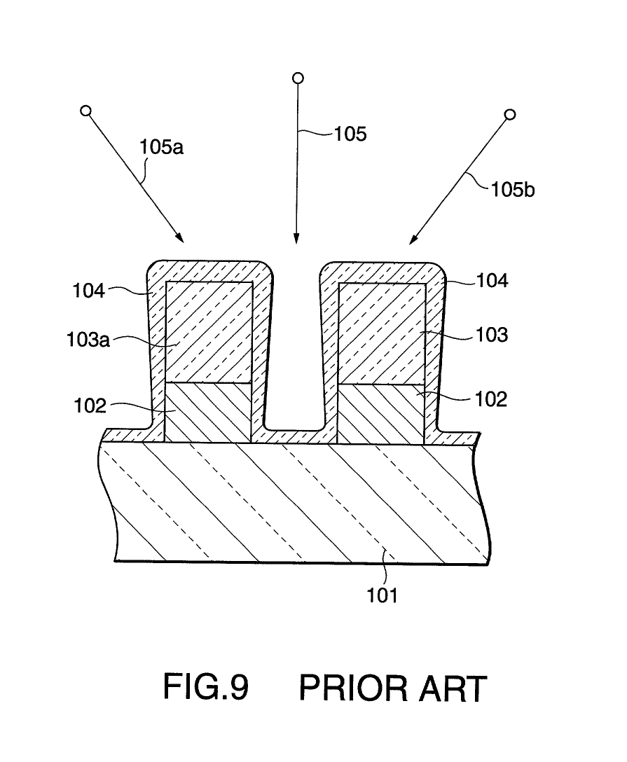

Next, a method for forming a silicon nitride film representing a first example of this invention will be described with reference to FIGS. 1 to 5. FIG. 1 is a sketchy cross-section of a reaction chamber introduced for illustrating the method of the present invention. FIG. 2 is a cross-section of a wiring portion which has a silicon nitride film coated thereupon, the silicon nitride film being applied to cover the entire wiring pattern similar to that of FIG. 9. Then, FIGS. 3 and 4 are graphs for illustrating the control conditions required when the above-described silicon nitride film is formed. FIG. 5 is a graph for illustrating the insulating activity of a silicon nitride film prepared according to this invention.

Firstly, how a silicon nitride film is formed will be described with reference to FIG. 1. Reaction chamber 1 has internal walls consisting of alumite-treated stainless steel. Reaction chamber 1 contains a heating portion 2 and an ignition plate 3, and a wafer 4 is placed on the ignition plate 3. The ignition plate is made of aluminum nitride high in thermal transmission, and its temperature, or the film-forming temperature is set to 700 to 800° C.

Then, SiH4 and NH3 as reactive gases and N2 as a carrier gas are introduced from a gas inlet 5, and allowed to enter reaction chamber 1 through a shower head 6. Reaction chamber 1 is connected through a gas outlet 7 to a pump. During the formation of a film, the pressure of all gases contained in reaction chamber 1 is kept at about 4×10⁴ Pa under the control of the pump.

Formation of a silicon nitride according to the method of this invention comprises using SiH4 and NH3 as reactive gases, setting the film-forming temperature at 750 to 800° C., and maintaining the pressure of all gases contained in the reaction chamber at a level 102 to 103 times higher than that encountered with conventional thermal CVD.

Next, how a silicon nitride film is formed on the surface of a wiring pattern where each lead has an aspect ratio as high as the example of FIG. 9 will be described with reference to FIG. 2. As shown in FIG. 2, leads 12, 12a parallel with each other are formed on the surface of an inter-layer insulating film 11. In this particular example, the width of each lead and the interval between the two leads are both equal to 0.2 μm. Leads 12, 12a are made of tungsten (W), and each has a thickness of 100 nm. Then, masks 13, 13a consisting of a nitride film are formed on leads 12, 12a, respectively. Masks 13, 13a made of a nitride film have a thickness of about 300 nm.

In this manner, components of the underlying pattern, that is, lead 12, and mask 13 of nitride film, and lead 12a, and mask 13a of nitride film are formed. Thus, a wiring pattern where each component has a high top-base step is formed over the inter-layer film 11.

Over the entire surface of the basement structure as described above, a silicon nitride film having a thickness of about 50 to 60 nm is deposited as a silicon nitride film of this invention, that is, a blanket nitride film 14 is applied over the inter-layer insulating film 11 so that the film can intimately cover the top and lateral surfaces of each component of the pattern over the inter-layer insulating film 11.

As shown in FIG. 2, the blanket nitride film 14 does not develop any overhangs that are encountered with a similar nitride film prepared by conventional thermal CVD. Even when the comparatively high gas pressure characteristic with the method of this invention for the formation of a silicon nitride film is altered to 1×104 to 6×104 Pa, the resulting nitride film will be free from such overhangs. For example, if the pressure of all the gases is kept at 4×104 Pa, the average free travel distance of active molecules such as those as described with respect to the conventional technique will become about 80 nm. In FIG. 2, the average free travel distance of each active molecule 15 is represented by the length of the arrow attached to the molecule. As is obvious from FIG. 2, this average free travel distance is shorter than the dimension of the inter-component space. Thanks to this, active molecules 15 thermally agitated will be relieved of the shadowing effect, and thus, so it is believed, the nitride film will be devoid of overhangs as described above. However, the thickness of the film section covering the top of a component of the pattern, and the thickness of the film section covering the lateral surface of the same component are not always the same. This difference results from the film-formation condition as will be described later. As shown in FIG. 2, the thickness of the film section covering the top of a component is taken as a, while the thickness of the film section covering the lateral surface of the same as b, and the value b/a to represent the step coverage of the film.

The present inventors undertook many trials in order to improve the step coverage value for a given nitride film, and found a method for easily controlling the step coverage value. What advantage is brought about by an improved step coverage value will be described below with reference to a case where a silicon nitride film prepared as above is applied for the formation of a semiconductor device.

The inventors minutely studied, with regard to the formation of a silicon nitride film as described above, the changes in refractive index of the silicon nitride film by altering the flow ratio of reactive gases such as NH3 and SiH4 responsible for the deposition of the film. It is possible to easily determine the refractive index of a silicon nitride film with a refractometer. The relationship of the refractive index of a silicon nitride film with the flow ratio of NH3/SiH4 responsible for the formation of the film is represented in FIG. 3. For this measurement, the film-formation temperature was set to 750° C. while the pressure of all the gases to 4×104 Pa.

As is obvious from FIG. 3, the refractive index of a silicon nitride film rapidly declines with the increase of the flow ratio of HN3/SiH4, but does not show any further change or becomes saturated when the flow ratio is 130 or more. This dependency of the refractive index of a silicon nitride film on the flow ratio of NH3/SiH4 is comparatively independent of the film-formation temperature. The above dependency remains the same even if the pressure of all the gases is altered in the range of 1×104 to 6×104 Pa.

The minute study by the inventors further revealed that it is possible to easily control the step coverage of a silicon nitride film by adjusting its refractive index. This finding will be described with reference to FIG. 4.

FIG. 4 is a graph representing the relationship of the step coverage value of a silicon nitride film on a lead of a pattern obtained by the method explained in FIG. 3, with the real value component of refractive index of the film. As is obvious from FIG. 4, the step coverage value is maintained almost at 100% as long as the real value component of refractive index is in the range of 1.96 to 1.98. However, when the refractive index exceeds the above range, the step coverage rapidly declines, and when the refractive index becomes 2.0 or more, the step coverage reaches a minimum or 80% and keeps almost the same level. The step coverage value of a film depends on the aspect ratio of the lead to which the film is applied: the step coverage of a film decreases with the increased aspect ratio of the lead to which the film is applied. However, regardless of the aspect ratio of a given lead, the step coverage of a silicon nitride film applied to the lead always rapidly changes when the real value component of refractive index of the film exceeds 1.98.

For reliably mass-producing semiconductor devices, it is important to check the step coverage of a silicon nitride film, after applying the film to a semiconductor device. This is because, if a silicon nitride film is applied onto a wafer, and then it is possible to check whether the assembly is satisfactory or not, based on the step coverage of the film, and to thereby eliminate in advance wafers possibly leading to the production of defective products, it will be very effective for reducing the cost required for the mass-production of semiconductor devices.

The conventional method for checking the step coverage of a silicon nitride film consists of forming a silicon nitride film on a semiconductor substrate, and then of observing, by SEM (secondary electronmicroscopy), the cross-section of a pattern of semiconductor elements on the semiconductor substrate sampled from a product lot for checking. This method becomes an essential technique required for the compaction of semiconductor elements.

The above-mentioned study by the inventors revealed, however, that it is possible to easily control the step coverage of a silicon nitride film through the observation of the refractive index of the silicon nitride film. The refractive index of a silicon nitride film can be easily determined with a refractometer. Thus, the method of this invention for checking the step coverage of a silicon nitride film applied onto the surface of a semiconductor substrate sampled for checking comprises a technique by which to determine the refractive index of the film. This is a markedly simple technique as compared with the conventional method based on the SEM observation. The method further comprises feeding back the result of checking to the process for the formation of a silicon nitride film for subsequent improvement. In this manner, the refractive index of a silicon nitride film is monitored and the monitoring result is used for the control of the film formation process itself.

Ordinarily, the refractive index of a silicon nitride film is expressed by a complex number, and its imaginary number component is ascribed to light absorption. According to the method of this invention, a silicon nitride film is formed so as to give a refractive index whose real number component does not exceed 1.98, in accordance with the characteristics obvious in FIGS. 3 and 4, or, as mentioned above, under a condition where the flow ratio of NH3/SiH4 during formation of the film is kept at 130 or more.

It is also possible to monitor the refractive index of a silicon nitride film during the formation of the film, that is, to exercise an in-situ process monitoring. In this case, a refractometer is attached to the reaction chamber described in relation with FIG. 1. The basic composition comprises, for example, a measurement system whereby a laser beam for measurement is radiated from outside to enter the reaction chamber, and the polarization of emergent beam is determined.

Next, the insulation of a silicon nitride film prepared as above will be described with reference to FIG. 5. FIG. 5 shows how much electric current passes through a silicon nitride film when voltage applied to the film varies. Of the graph, the abscissa represents the magnitude of the electric field applied, while the ordinate the density of electric current, with the refractive index of the silicon nitride film being altered as a parameter. As shown in FIG. 5, the density of current monotonously increases with the increase of applied voltage. However, this increment of current density decreases with the decrease of refractive index of the silicon nitride film. Through this observation, it is found that improving the insulation of a silicon nitride film is possible by decreasing the refractive index of that film.

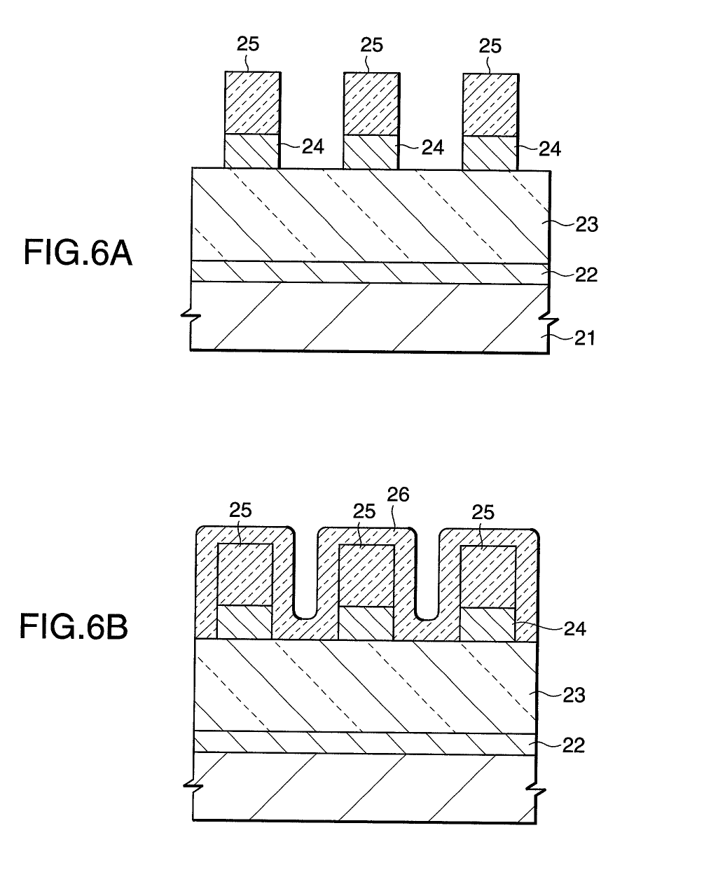

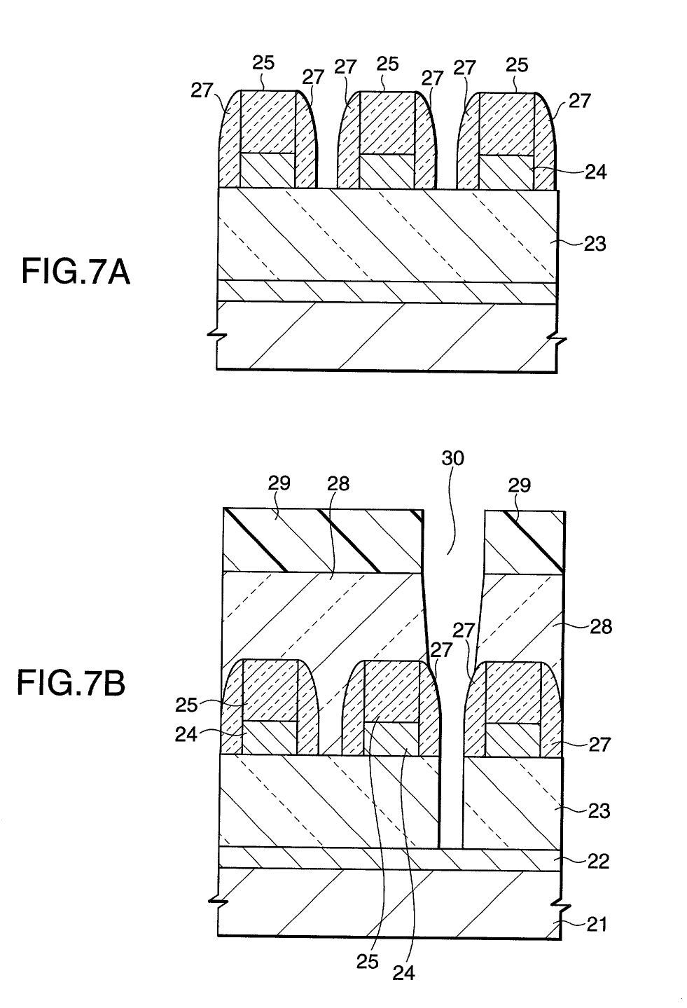

Next, as a second example of this invention, a method for forming a silicon nitride film through SAC will be described with reference to FIGS. 6 and 7. In the description, the reason why the method will improve the step coverage of a silicon nitride film will also be mentioned. FIGS. 6 and 7 show the cross-sections of a pattern arranged in the sequential order of SAC process.

An N-type diffusion layer 22 is formed through ion injection and thermal treatment on the surface of a P-type silicon substrate 21. Then, a first inter-layer insulating film 23 having a thickness of about 500 nm is formed. Formation of the first inter-layer insulating film 23 consists of depositing a silicon oxide film by CVD, and flattening the silicon oxide film by CMP (chemicomechanical polishing). Deposition of this silicon oxide film to serve as a first dielectric body is achieved by the publicly known plasma CVD.

Next, over the first flattened inter-layer insulating film 23 is formed by CVD or by sputtering a film of a metal such as tungsten (W) about 50 nm in thickness, or a laminated metal film comprising a W-based metal film and a WN (tungsten nitride)-based metal film. Then, a protective nitride film is formed on the metal film by CVD. The protective nitride film is a silicon nitride film 200 nm in thickness to serve as a second dielectric body. The film formation temperature used in the thermal CVD is 750 to 800° C., and the reactive gas necessary for the formation of the nitride film comprises a mixture gas of silane (SiH4) and ammonia (NH3). Then, applying the publicly known photolithography and dry-etching techniques for the processing of the nitride and metal films makes it possible to dry-etch the two films in correspondence with a same pattern. Dry-etching of the metal film is achieved by RIE (reactive ion etching), or with a plasma etching apparatus based on the use of ICP (inductive coupled plasma), or of μ-wave excitation (ECR). Preparation of the reactive gas to be used for dry etching is achieved by taking a mixture gas comprising SF6, N2 and C12, and by adding thereto a gas such as CF4 or C4F8.

In this manner, as shown in FIG. 6A, leads 24 and nitride film masks 25 constituting a pattern are layered. In this particular example, the width of each lead 24 and nitride mask 25, and the interval between adjacent leads are both 0.2 μm.

Next, the assembly is subjected to the publicly known oxygen plasma treatment (ashing) and then to the treatment based on the use of diluted solution of hydrofluoric acid. The diluted solution of hydrofluoric acid (DHF hereinafter) used for this treatment is obtained by mixing 49% hydrofluoric acid and pure water at a ratio of 1/100 in volume. The assembly is immersed in DHF for 10 sec, and the debris produced as a result of the dry etching of metal film 4 are removed therewith. For this purpose, DHF may comprise ammonium fluoride solution as a constituent of the mixture.

Then, as shown in FIG. 6B, a silicon nitride film is formed over the assembly by thermal CVD as described above in relation with the first example, such that a blanket nitride film 26 about 50 to 60 nm in thickness is formed on the entire surface of the assembly. The blanket nitride film 26 serves as a second dielectric body. The film formation temperature used in thermal CVD is 750 to 800° C., and the reactive gas necessary for the formation of a nitride film comprises a mixture gas of silane (SiH4) and ammonia (NH3). In this thermal CVD, the ratio of the flow of NH3 against that of SiH4, both being reactive gases, is set to about 130. Through this arrangement it is possible to apply the blanket nitride film 26 onto the patterned leads 24 and nitride film mask 25, and first inter-layer insulating film 23 in such a way as to allow the film 26 to give a step coverage of 100%. To attain this, the condition of the above thermal CVD is adjusted such that the pressure of all the reactive gases is maintained at 4×104 Pa, or a level ¼ to ½ of the normal pressure.

Through this arrangement, it is possible to allow the section of the blanket nitride film 26 correspondent to the surface of first inter-layer insulating film 23 exposed between adjacent leads 24, the section correspondent to the lateral surface of each lead 24, and the section correspondent to the top surface of nitride film mask 25 to have a same thickness, or, in other words, to uniformly apply the blanket nitride film 26 onto the assembly.

Then, total-surface etching is applied to the blanket nitride film 26 by subjecting the film to the total-surface etching based on anisotropic dry-etching, that is, etching-back. Through this process, it is possible for side-wall nitride films 27 about 50 nm in thickness to be formed on the lateral surfaces of each component comprising a lead 24 and nitride film mask 25 as shown in FIG. 7A. To be used in this process, a mixture gas comprising NF3 and N2 or reactive gases is excited into plasma. In the presence of such an etching gas, the ratio of the etching rate of silicon oxide film against that of silicon nitride film is kept low, and moreover etching of the surface of first inter-layer insulating film 23 is kept minimized during this etching-back process. The side-wall nitride film 27 serves as-a protective insulating film for nitride film mask 25 as well as for lead 24.

In addition, according to this invention, even when a blanket nitride film 26 is applied to a component of a pattern having an emphasized top-base step or a high aspect ratio as described above, it is possible to allow the film 26 to present with a satisfactory step coverage. Because of this, it is also possible to precisely form a side-wall nitride film 27 having a uniform thickness during the etching-back process. If a blanket nitride film 26 presents with an unsatisfactory step coverage as encountered with a similar film prepared by the conventional thermal CVD, nitride film masks 25 and side-wall nitride films 27 on a wafer will show a great variation in thickness during the etching-back process. As is obvious from above, according to this invention, it is possible to stably form a protective film on each lead 24 even in the mass-production of semiconductor devices.

Next, the assembly is subjected to the publicly known oxygen-plasma treatment, and to the aforementioned DHF-based treatment. Specifically, the assembly is immersed in DHF for 10 seconds, and debris such as organic polymers adherent to the surfaces of nitride film mask 25, side-wall nitride film 27 and first inter-layer insulating film 23 are removed.

Next, a second inter-layer insulating film 28 about 500 nm in thickness is formed. Preparation of the second inter-layer insulating film 28 is achieved by depositing a silicon oxide film on the assembly by CVD, and then by flattening the silicon oxide film by CMP. Then, a resist mask 29 with a contact hole pattern is applied onto the assembly by the publicly known photolithography technique; resist mask 29 is used to serve as a mask in etching; and second and first inter-layer insulating films 28 and 23 are dry-etched in succession. Through this process, prepared is a contact hole 30 between adjacent leads 24 which penetrates second and first inter-layer insulating films 28 and 23 to reach the diffusion layer 22 of the superficial layer of a silicon substrate 21, as shown in FIG. 7B. During this process, side-wall nitride film 27 and nitride film mask 25 prevent leads 24 from being etched.

Dry-etching necessary for the formation of contact hole 30 is performed by RIE based on the use of two RFs. In this process, plasma excitation is achieved by the use of an RF with a frequency of 13.56 to 60 MHz. Then, another RF with a frequency of about 1 MHz is added. In the RIE based on the use of two RFs, a mixture gas of C4F8, O2 and argon (Ar), i.e., reactive gases are subjected to plasma excitation. When such an etching gas is used, the etching ratio of silicon oxide film vs. silicon nitride film becomes large and thus etching of the side-wall nitride film 27 and nitride film mask 25 during this process based on RIE is negligible. During this RIE process introduced for the formation of contact hole 30, side-wall nitride film 27 serves as an etching mask for first inter-layer insulating film 23.

Next, resist mask 29 is removed by oxygen plasma ashing, and the assembly is treated with DHF in the manner as described above. Specifically, the treatment consists of immersing the assembly into DHF for 10 seconds, thereby eliminating the contaminants such as fluorine-containing organic polymers and heavy metals developed during the formation of contact hole 30.

The subsequent processes, although they are not illustrated here, are introduced for inserting a contact plug into contact hole 30, and for then forming an overlying lead so as to allow the lead to achieve appropriate connection with the contact plug.

According to this invention, side-wall nitride film 27 is integrally combined with nitride film mask 25 on lead 24, such that the two films together serve as a protective film for the lead during etching. Thus, nitride film mask 25 and side-wall nitride film 27 formed around lead 24 are used as a mask during RIE etching introduced for the formation of contact hole 30.

Further, the insulation of a silicon nitride film prepared according to this invention is increased, as described above with respect to Example 1. Because of this, insulation between lead 24 and a contact plug inserted into contact hole 30 is greatly improved.

In this manner, it is possible to prepare a contact hole in a self-alignment manner with respect to lead 24, and thus to greatly increase the surface density of semiconductor elements mounted on a substrate, that is, to achieve the high-density integration of a semiconductor device.

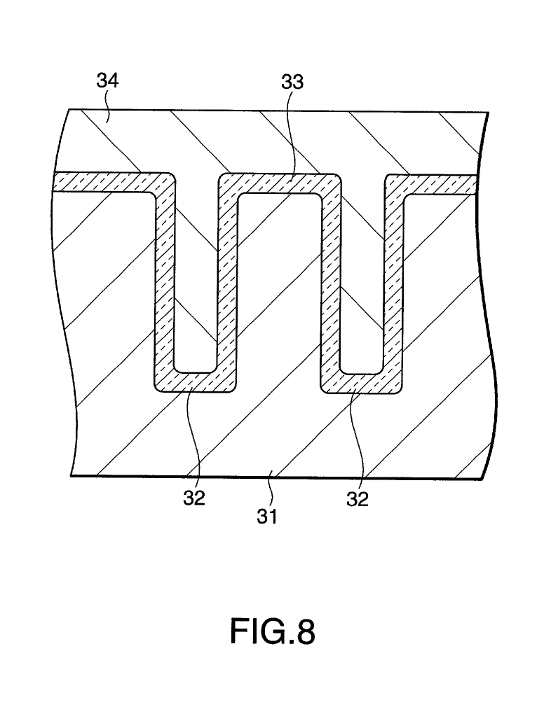

Next, description will be given, with reference to FIG. 8, of Example 3 of this invention where the above formation of a silicon nitride film is introduced for the formation of an insulating layer of a capacitor. FIG. 8 is a sketchy cross-section of a capacitor with a trench structure.

Trenches 32 are formed on the front surface of a silicon substrate by the known photolithography and dry-etching techniques, as shown in FIG. 8. In this particular example, the trench 32 has a depth of 5 μm and a width of 0.5 μm. Thus, the aspect ratio of a trench is 10. Then, a capacitive nitride film 33 is formed so as to cover the base and lateral surfaces of each trench 32, and the front surface of silicon substrate 31. This process may consist of forming a silicon oxide film over the inner surfaces of each trench 32, and then of forming a capacitive nitride film 33.

Formation of a capacitive nitride film 33 is achieved by thermal CVD described above with respect to Example 1. The silicon nitride film formed by this process has a thickness of about 100 nm. Also in this thermal CVD, the film formation temperature is 750 to 800° C., and the reactive gas necessary for the formation of a nitride film comprises a mixture gas of SiH4 and N3. The ratio of the flow of NH3 against that of SiH4, both being reactive gases, is set to about 150. A condition of the thermal CVD, for example, the pressure of all the reactive gases is set to about 4×104 Pa. Through this arrangement it is possible to have a blanket nitride film applied to a trench 32 with a step coverage of 100%. In addition, insulation of capacitive nitride film 33 is greatly improved.

Next, a polycrystal silicon layer doped with phosphor is formed so as to cover the capacitive nitride film 33, and the layer is patterned to give a capacitor electrode 34. Thus, formed is a capacitor which comprises silicon substrate 31 and capacitor electrode 34 as opposite electrodes with capacitive nitride film 33 as a capacitive insulating layer. Such a capacitor is most useful when the high-density formation of large-capacity capacitors is required as in the production of an analog device.

In the above-described examples, NH3 and SiH4 are used as reactive gases for the formation of a silicon nitride film. According to this invention, SiH4 may be substituted for fluorosilane such as SiHxFy to achieve the same effect.

Formation of a silicon nitride film according to this invention occurs while the pressure of all reactive gases is kept at a very high level as compared with the conventional thermal CVD. However, if the pressure in question is raised as high as normal pressure, problems may arise. The preferable range of the pressure is not determined yet, but, according to the study hitherto made, the pressure of all reactive gases should be kept in the range of 1×104 to 6×104 Pa. In this process, if the gas pressure is kept too low, the rate of film formation will be reduced, while if the gas pressure is kept too high, the silicon nitride film will show a wide variation in its thickness, with the enhanced development of particles thereupon, and thus the process will be completely unsuitable for the mass-production of semiconductors.

With the above-described examples of this invention, the pressure of all reactive gases is kept sufficiently high to allow the average free travel distance of reactive gas molecules to be shorter than the distance between adjacent leads of a pattern which will have a film formed thereupon. However, it should not be understood this invention only applies to the above cases. Also, if formation of a silicon nitride film on a pattern consisting of a single lead is required, it will be useful to shorten the average free travel distance of reactive gas molecules by keeping the pressure of reactive gases at a high level. This effect will be also felt if film formation is made against an underlying pattern having an improper shape.

Application of this invention for the production of a semiconductor device has been described on the premise that wiring patterns are connected through layered metals made of W or WN. However, this invention is not limited to the devices incorporating those metals. This invention is similarly applicable to the semiconductors where the connector metal is made of a high-melting point metal such as molybdenum (Mo), tantalum (Ta), titanium (Ti), etc., or a precious metal such as platinum (Pt), Ruthenium (Ru), etc.

Description of the above examples has been given on the premise that the first dielectric body is a silicon oxide film. The first dielectric body, however, may be substituted for a Si—O based film with a low dielectric constant. The insulating film may include a low permittivity film made of a material chosen from silsesquioxanes such as hydrogen silsesquioxane, methyl silsesquioxane, methylated hydrogen silsesquioxane, and fluorinated silsesquioxane.

This invention is not limited to the above examples, but can be varied as appropriate within the technical concept underlying this invention.

As discussed above, the method of this invention for fabricating a semiconductor device comprises the steps of adopting thermal CVD with ammonia and silane or fluorosilane used as reactive gases, and keeping the pressure of gases in a reaction chamber high, thereby forming a silicon nitride film with a high step coverage on a pattern where each lead has a high top-base step, laid over a semiconductor device. With this method, the total pressure of all gases including inert as well as reactive gases is kept so high as to allow the average free travel distance of reactive gas molecules within the reaction chamber which contains an inert gas as well as reactive gases, to be smaller than the interval between adjacent leads of a pattern where each lead has a high top-base step, the pattern being formed on the surface of a semiconductor substrate.

In another aspect, the method of this invention for fabricating a semiconductor device comprises the steps of adopting NH3 and SiH4 as reactive gases, and of adjusting the inflow of the reactive gases to the reaction chamber such that the flow ratio of NH3 vs. SiH4 is 130 or more.

In a still further aspect, the method of this invention for fabricating a semiconductor device comprises the step of forming a silicon nitride film by thermal CVD with NH3 and SiH4 used as reactive gases while monitoring the refractive index of the forming silicon nitride film and controlling the operation according to the monitoring result. For this, process-control is introduced such that the real value portion of refractive index does not exceed 1.98.

In a still further aspect, the method of this invention for fabricating a semiconductor device comprises the step of forming a silicon nitride film on a semiconductor device by SAC, or of using a silicon nitride film for the preparation of a capacitor.

As discussed above, according to this invention, it is possible to easily form a silicon nitride film excellent in insulation and high in step coverage on a semiconductor substrate. Moreover, not only controlling the formation of a silicon nitride film is simplified but mass-production of semiconductors becomes easy.

Further, if a silicon nitride film prepared as above is applied for the formation of a semiconductor device having a fine structure, it will be possible to promote the high-integration and high-density of semiconductor devices. Furthermore, it will be also possible to maintain the yield to a high level, thereby reducing the cost necessary for production of semiconductor devices.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A method for manufacturing a semiconductor device by thermal CVD with NH₃ and SiHₓF₄₋ₓ (x=0, 1, 2, 3 or 4) used as reactive gases comprising the steps of:
setting the pressure of reactive gases in a reaction chamber in the range of 1×10⁴ to 6×10⁴ Pa; and
forming a silicon nitride film on the surface of a pattern where each lead has an enhanced step, placed on a semiconductor substrate.

2. A method for manufacturing a semiconductor device as described in claim 1 wherein, for the reaction chamber into which an inert gas as well as reactive gases have been introduced, the total pressure of the reactive gases and inert gas within the chamber is set in the range of 1×10⁴ to 6×10⁴ Pa so as to allow the average free travel distance of reactive gas molecules within the reaction chamber, to be smaller than the distance between adjacent leads of a pattern where each lead has an enhanced step, placed on a semiconductor substrate.

3. A method for manufacturing a semiconductor device as described in claim 1 wherein the pattern placed on a semiconductor substrate where each component has an enhanced step is a wiring pattern or a trench pattern.

4. A method for manufacturing a semiconductor device as described in claim 1 wherein the reactive gas comprises NH3 and SiH4, and the rate of inflow of NH3 gas against that of SiH4 gas to the reaction chamber is kept 130 or more.

5. A method for manufacturing a semiconductor device comprising the steps of:
forming, from a silicon oxide film, a first inter-layer insulating film which is intimately applied onto a diffusion layer formed on the surface of a semiconductor substrate or onto an underlying lead formed on a semiconductor substrate;
placing an overlying lead on the first inter-layer insulating film in parallel with the latter and forming, on the top and lateral surfaces of the overlying lead, a protective insulating film made of a silicon nitride film; and
applying dry etching to the above structure with the protective insulating film used as a part of etching mask, so as to allow a contact hole to be formed which penetrates the first inter-layer insulating film to reach the diffusion layer or the underlying lead, wherein:
thermal CVD with NH₃ and SiHₓF₄₋ₓ (x=0, 1, 2, 3 or 4) used as reactive gases is introduced for the formation of the silicon nitride film while the pressure of reactive gases is kept in the range of 1×10⁴ to 6×10⁴ Pa.

6. A method for manufacturing a semiconductor device comprising the steps of:
forming, from a silicon oxide film, a first inter-layer insulating film which is intimately applied onto a diffusion layer formed on the surface of a semiconductor substrate or onto an underlying lead formed on a semiconductor substrate;
placing an overlying lead on the first inter-layer insulating film in parallel with the latter and forming, on the top and lateral surfaces of the overlying lead, a protective insulating film made of a silicon nitride film;
forming, from a silicon oxide film, a second inter-layer insulating film so as to allow it to rest on the first inter-layer insulating film to cover the protective insulating film; and
forming a resist film having a contact hole pattern thereupon on the second inter-layer insulating film, applying dry etching to the above structure with the resist film used as an etching mask, so as to allow a contact hole to be formed which penetrates the second inter-layer insulating film, and immediately applying dry etching to the first inter-layer insulating film with the protective insulating film used as a mask, so as to allow a contact hole to reach a diffusion layer or an underlying lead, wherein:
thermal CVD with NH₃ and SiHₓF₄₋ₓ (x=0, 1, 2, 3 or 4) used as reactive gases is introduced for the formation of the silicon nitride film while the pressure of reactive gases is kept in the range of 1×10⁴ to 6×10⁴ Pa.
